(19) United States
(12) Patent Application Publication
(10) Pub. No.: US 2023/0155085 A1
(43) Pub. Date: May 18, 2023

(54) OPTOELECTRONIC COMPONENT AND ILLUMINATION DEVICE

(71) Applicant: ams-OSRAM International GmbH, Regensburg (DE)

(72) Inventor: Laura Kreiner, Regensburg (DE)

(21) Appl. No.: 17/917,379

(22) PCT Filed: Apr. 1, 2021
(86) PCT No.: PCT/EP2021/058572

§ 371 Date: Oct. 6, 2022

(30) Foreign Application Priority Data
Apr. 8, 2020 (DE) 10 2020 204 538.0

(51) Int. Cl. H01L 33/60

(52) U.S. Cl. CPC H01L 33/60

(57) ABSTRACT

An optoelectronic component includes a semiconductor body having an active region that generates primary electromagnetic radiation and an exit surface; an optical element arranged downstream of the exit surface that deflects and/or converts radiation generated in the component; and a dielectric mirror between the exit surface and the optical element, wherein the dielectric mirror is transmissive to radiation of a predetermined wavelength generated in the component and incident at angles of incidence in a predetermined first angular range, and is reflective to the radiation of the predetermined wavelength incident at angles of incidence in a predetermined second angular range.

### TECHNICAL FIELD

This disclosure relates to an optoelectronic component and an illumination device.

### BACKGROUND

One task to be solved is to provide an optoelectronic component that emits radiation efficiently. Another problem to be solved is providing an illumination device comprising such an optoelectronic component.

### SUMMARY

I provide an optoelectronic component including a semiconductor body having an active region that generates primary electromagnetic radiation and an exit surface, an optical element arranged downstream of the exit surface that deflects and/or converts radiation generated in the component, and a dielectric mirror between the exit surface and the optical element, wherein the dielectric mirror is transmissive to radiation of a predetermined wavelength generated in the component and incident at angles of incidence in a predetermined first angular range, and is reflective to the radiation of the predetermined wavelength incident at angles of incidence in a predetermined second angular range.

I also provide an illumination device including the optoelectronic component including a semiconductor body having an active region that generates primary electromagnetic radiation and an exit surface, an optical element arranged downstream of the exit surface that deflects and/or converts radiation generated in the component, and a dielectric mirror between the exit surface and the optical element, wherein the dielectric mirror is transmissive to radiation of a predetermined wavelength generated in the component and incident at angles of incidence in a predetermined first angular range, and is reflective to the radiation of the predetermined wavelength incident at angles of incidence in a predetermined second angular range, and a light guide with an in-coupling side via which radiation coming from the component is coupled into the light guide during operation.

I further provide an optoelectronic component including a semiconductor body having an active region that generates primary electromagnetic radiation and an exit surface, a meta lens located downstream of the exit surface, and a polarization filter between the meta lens and the exit surface, wherein the meta lens is formed from at least two materials of different refractive indices, and the materials are arranged in succession along the main extension plane so that the meta lens has a patterning in refractive index in directions parallel to its main extension plane.

I further yet provide an optoelectronic component including a semiconductor body having an active region that generates primary electromagnetic radiation and an exit surface, an optical element arranged downstream of the exit surface that deflects and/or converts radiation generated in the component, and a dielectric mirror between the exit surface and the optical element, wherein the dielectric mirror is transmissive to radiation of a predetermined wavelength generated in the component and incident at angles of incidence in a predetermined first angular range, and is reflective to the radiation of the predetermined wavelength incident at angles of incidence in a predetermined second angular range, and the optical element comprises a deflection structure configured such that radiation from the component passing through the deflection structure is scattered in an x-direction and is less or not scattered in a y-direction, perpendicular to the x-direction.

### BRIEF DESCRIPTION OF THE DRAWINGS

FIGS. 1 to 9 show examples of the optoelectronic component in various views.

FIG. 10 shows an example of the far field generated by a component.

FIGS. 11 to 15 show examples of illumination devices in various views.

### LIST OF REFERENCE SIGNS

1 semiconductor body
2 exit surface
3 dielectric mirror
4 optical element/deflection structure
5 optical element/meta lens
6 polarization filter
7 optical element/conversion element
8 further dielectric mirror
9 planarization layer
9a side of the planarization layer
10 optoelectronic component
11 glass platelet
20 light guide
21 in-coupling side
30 aperture
40 scattering side
41 trench
42 encapsulation layer
50 lens
α angle
β angle
S1 curve
S2 curve

### DETAILED DESCRIPTION

Our optoelectronic component may comprise a semiconductor body having an active region that generates primary electromagnetic radiation. Furthermore, the semiconductor body has an exit surface.

For example, the semiconductor body is based on a III-V compound semiconductor material. The semiconductor material is, for example, a nitride compound semiconductor material such as AlₙIn₁₋ₙ₋ₘGaₘN, or a phosphide compound semiconductor material such as AlₙIn₁₋ₙ₋ₘGaₘP, or an arsenide compound semiconductor material such as AlₙIn₁₋ₙ₋ₘGaₘAs or AlₙIn₁₋ₙ₋ₘGaₘAsP, where 0≤n≤1, 0≤m≤1, and m+n≤1, respectively. The semiconductor body may have dopants as well as additional components. For simplicity, however, only the essential constituents of the crystal lattice of the semiconductor body, i.e., Al, As, Ga, In, N or P, are indicated, even if these may be partially replaced and/or supplemented by small amounts of additional substances. Preferably, the semiconductor body is based on AlInGaN.

The active region of the semiconductor body includes in particular at least one pn junction and/or at least one quantum well structure in the form of a single quantum well, SQW for short, or in the form of a multi-quantum well structure, MQW for short. For example, the active region generates primary electromagnetic radiation in the blue or green or red spectral range or in the UV range or in the IR range during intended operation.

The primary radiation generated during operation is in particular incoherent radiation. The component is in particular a light-emitting diode (LED) or a light-emitting diode chip (LED chip).

The exit surface forms a top surface of the semiconductor body and is formed from the material of the semiconductor body. In the intended operation of the component, a major part, i.e., at least 50% or at least 75% or at least 90%, of the primary radiation emitted by the semiconductor body exits the semiconductor body via the exit surface. In particular, during operation, more radiation exits the semiconductor body via the exit surface than enters. For example, at least twice as much or at least five times as much or at least ten times as much radiation exits as enters. On a rear side of the semiconductor body opposite to the exit surface, a mirror layer is preferably arranged, which is reflective, for example, for the entire visible spectrum and/or the primary radiation. The mirror layer may comprise a metallic layer and/or a dielectric layer.

The optoelectronic component is, for example, a semiconductor chip or a so-called chip-size package component. Both in a semiconductor chip and a chip-size package component, its lateral dimensions, measured parallel to a main extension plane of the semiconductor body, essentially correspond to the lateral dimensions of the semiconductor body. In particular, the lateral dimensions of the component are then at most 20% or at most 10% or at most 5% larger than those of the semiconductor body. Lateral surfaces of the component extending transversely to the main extension plane may have traces of a separation process resulting from a separation from a wafer composite. In a chip-size package device, the side surfaces are made of a potting material such as epoxy.

The component may be free of the growth substrate on which the semiconductor body is grown. In particular, the component is a thin film chip or a component with a thin film chip.

The component can be pixelated such that the semiconductor body comprises several individually and independently controllable emission areas (pixels). During operation of the emission regions, primary radiation is emitted via a partial area of the exit surface assigned to each such emission region. For example, the semiconductor body is divided into at least four or at least 10 or at least 50 or at least 1000 emission regions.

The optoelectronic component may comprise an optical element that deflects and/or converts radiation generated in the component. The optical element is arranged downstream of the exit surface along the main radiation direction of the primary radiation emerging from the exit surface. In top view, the optical element covers most or all of the exit surface. Preferably, the optical element is arranged on the exit surface.

The optical element is specifically configured to affect radiation generated in the component. For example, a thickness of the optical element measured perpendicular to the main extension plane of the semiconductor body is at least λ/4 or at least λ/2 or at least λ, wherein λ, is the wavelength at which the primary radiation or radiation incident on the optical element during operation has a global intensity maximum. The optical element may be a lens or a deflection structure or a conversion element.

The optoelectronic component may comprise a dielectric mirror between the exit surface and the optical element. The dielectric mirror is, for example, a periodic structure, i.e., a Bragg mirror, or a non-periodic structure.

The dielectric mirror preferably comprises multiple, for example, at least two or at least four or at least ten or at least 50 or at least 100, dielectric layers stacked with respect to the exit surface. The dielectric layers of the dielectric mirror are, for example, alternately high-refractive and low-refractive. The refractive index of a high-refractive layer differs from that of a low-refractive layer by at least 0.1 or at least 0.3 or at least 0.5 or at least 1.0. For example, the low-refractive layers have a refractive index of at most 2. For example, the high refractive layers have a refractive index of at least 2.3. The values for the refractive index are given here for the primary radiation.

For example, in the dielectric mirror, the dielectric layers alternate such that between every two high refractive layers there is a low refractive layer and vice versa. In a periodic structure, the thicknesses of all dielectric layers are the same within the manufacturing tolerance. In a non-periodic structure, the thicknesses of the dielectric layers vary.

The low refractive layers comprise or consist of, for example, at least one of the following materials: SiO₂, SiN, SiON, MgF₂. The high refractive layers comprise or consist of, for example, at least one of the following materials: Nb₂O₅, TiO₂, ZrO₂, HfO₂, Al₂O₃, Ta₂O₅, ZnO. The thicknesses of the dielectric layers are, for example, each 10 nm to 300 nm.

In a top view, the dielectric mirror and the optical element cover the exit surface and the semiconductor body, respectively, for the most part, for example, at least 80% or completely.

The dielectric mirror may be transmissive to radiation of a predetermined wavelength or a predetermined wavelength range generated in the component that is incident on the first dielectric mirror at angles of incidence in a predetermined first angular range. For radiation of the predetermined wavelength or range of wavelengths incident on the dielectric mirror with angles of incidence in a predetermined second angular range, the dielectric mirror is reflective. The first angular range and the second angular range preferably do not overlap.

Angles of incidence are measured herein as angles to a normal to the dielectric mirror. A normal to a dielectric mirror is understood to be a normal to the main extension plane of the dielectric mirror.

“Transmissive” means that an element transmits or passes at least 75%, preferably at least 90%, particularly preferably at least 99% of a radiation. “Reflective” means that an element reflects more than 75%, preferably at least 90%, particularly preferably at least 99% of a radiation.

The terms “predetermined first angular range” and “predetermined second angular range” refer to the fact that, when designing a dielectric mirror, the angular range in which it is transmissive and the angular range in which it is reflective can be precisely and desirably set by selecting the materials of the dielectric layers and the thickness of the dielectric layers. In this respect, the angular ranges for transmission and reflection can be predefined or selected or determined.

The terms “predetermined wavelength” or “predetermined wavelength range” refer to the fact that the just-mentioned angular selectivity of a dielectric mirror can usually be controlled only to a certain wavelength and a certain range around this wavelength. The choice of thicknesses and materials of the dielectric layers also plays a role. In this respect, when designing a dielectric mirror, a wavelength or wavelength range can be predetermined or selected or determined for which the dielectric mirror is to operate with selected angle selectivity.

The predetermined wavelength or wavelength range can be a wavelength or wavelength range in the spectrum of the primary radiation, for example, the wavelength at which the intensity of the primary radiation is at a maximum. Alternatively, the predetermined wavelength/wavelength range can also be a wavelength/wavelength range in the spectrum of a radiation that results from conversion in the component.

The optoelectronic component may comprise a semiconductor body having an active region for generating primary electromagnetic radiation and an exit surface. Further, the component comprises an optical element downstream of the exit surface for deflecting and/or converting radiation generated in the component and a dielectric mirror between the exit surface and the optical element. The dielectric mirror is transmissive to radiation generated in the component of a predetermined wavelength incident at an angle of incidence in a predetermined first angular range, and is reflective to radiation of the predetermined wavelength incident at an angle of incidence in a predetermined second angular range.

The optoelectronic component may comprise a semiconductor body having an active region that generates primary electromagnetic radiation and an exit surface. Furthermore, the component comprises a meta lens arranged downstream of the exit surface and a polarization filter between the meta lens and the exit surface. In particular, the meta lens is arranged on the exit surface.

We found that many optical elements used in optoelectronic components often function best only when the radiation generated in the component and incident on the optical element meets certain beam characteristics. For example, some optical elements are efficient only when the incident radiation impinges within a narrow angular range from the normal. For example, other optical elements operate efficiently only when the incident radiation is polarized. Some optical elements can also only work efficiently when both directional and polarized radiation is incident.

We thus arrange a selection element in the form of a dielectric mirror and/or a polarization filter in front of an optical element in an optoelectronic component. This selection element transmits only radiation of a predetermined wavelength in a predetermined first angular range and/or transmits only radiation of a predetermined polarization. This preselection of radiation then allows the optical element to operate more efficiently.

Our components are suitable, for example, as a radiation source for visible and invisible light in a headlight, in particular in a front headlight of a vehicle, or in a projector, or as a radiation source for sensor applications or for the backlighting of a display, for example, a smartphone display or a display for a vehicle interior.

The first angular range may comprise all angles of incidence between 0° and a measured to a normal to the dielectric mirror. The first angular range thus forms a cone with the normal as axis of rotation and an aperture angle of 2·α. For example, α has a value of at most 75° or at most 60° or at most 45° or at most 30° or at most 20° or at most 10°. Alternatively or additionally, the value for α is, for example, at least 5° or at least 10°.

The second angular range may comprise all angles of incidence of at least β measured with respect to the normal to the dielectric mirror, wherein β≥α. Preferably, β is at least 1° or at least 5° or at least 10° greater than α. Alternatively or additionally, β is at most 10° or at most 5° greater than α. Preferably, the second angular range includes all angles of incidence between and including β and 90°.

The dielectric mirror may have a transmittance of at least 75% or at least 90% or at least 99% for radiation of the predetermined wavelength/wavelength range incident with angles of incidence in the first angular range and a reflectance of at least 75% or at least 90% or at least 99% for radiation of the predetermined wavelength/wavelength range incident with angles of incidence in the second angular range. The specified values of the transmittance and the reflectance for radiation of the predetermined wavelength/the predetermined wavelength range particularly preferably apply to all angles of incidence in the respective angular range.

The optical element may comprise a deflection structure. The deflection structure is formed such that the radiation of the component passing through the deflection structure is scattered in an x-direction and is less or not scattered in a y-direction, perpendicular to the x-direction. For example, the x-direction and y-direction are both parallel to the main extension plane of the semiconductor body. For example, the deflection structure increases the aperture angle of the radiation in the x-direction by at least 50% or at least 100% or at least 200%. In the y-direction, for example, the aperture angle is increased by at most 50% or at most 20%.

In other words, if the radiant intensity distribution curve is considered in a sectional plane perpendicular to the main extension plane of the semiconductor body and parallel to the x-direction, the aperture angle of the distribution curve for the radiation immediately after passing through the deflection structure is at least 1.5 times or at least 2 times or at least 3 times the aperture angle of the radiant intensity distribution curve for the radiation immediately before passing through the deflection structure. If, on the other hand, the radiant intensity distribution curve is viewed in a sectional plane perpendicular to the main extension plane of the semiconductor body and parallel to the y-direction, then the aperture angle of the distribution curve of the radiation immediately after passing through the deflection structure is at most 1.5 times or at most 1.2 times the aperture angle immediately before passing through. The aperture angle is understood herein as the angular range in which the radiant intensity of the radiation has at least 50% of its maximum.

By adjusting the radiation to a first angular range, a particularly strong asymmetry of the aperture angles of the far field in x-direction and y-direction can subsequently be achieved with the deflection structure. In fact, such far-field patterns are desired in some applications of optoelectronic components. An example is the coupling of radiation from an optoelectronic component into a flat waveguide, where a strongly asymmetric far field is advantageous.

Thus, the dielectric mirror first restricts the radiation to a first angular range, which enables complete coupling of the radiation into the narrow side of the waveguide. The deflection structure then fans out the radiation in one spatial direction, which ensures that the broad side of the waveguide is illuminated as homogeneously as possible.

The deflection structure may have a structuring with trenches extending in the y-direction on a scattering side.

The trenches extend along the y-direction in particular in a straight line and preferably over the entire or almost the entire extent of the deflection structure in the y-direction. Preferably, in any sectional view parallel to the y-direction, the profile of the scattering side is flat within the manufacturing tolerance. In contrast, in sectional views parallel to the x-direction, the profile of the scattering side is structured with alternating elevations and depressions, the depressions being associated with the trenches extending in the y-direction. The elevations and depressions each taper to a point, for example. The heights of the elevations are, for example, each 100 nm to 50 μm.

At the scattering side, incident radiation is scattered in the x-direction and less or not scattered in the y-direction. The scattering side can be formed on a side of the deflection structure facing towards and/or away from the semiconductor body. The deflection structure is preferably formed of a material transparent to the radiation generated in the component. For example, the deflection structure is formed of glass or silicone or epoxy or plastic or SiO₂ or NbO₂ or TiO₂ or SiN. Preferably, the deflection structure is formed as a single piece or in one piece.

The scattering side can adjoin air or can be covered with an encapsulation layer that fills the trenches and is flat and/or smooth on a side facing away from the scattering side. In this example, the encapsulation layer preferably has a transparent material with a different refractive index than that of the deflection structure. The difference in refractive index ensures dispersion when passing through the scattering side. The flat and/or plane side of the encapsulation layer simplifies mounting of the component, for example, directly on an optical fiber/waveguide.

Such an optoelectronic component with dielectric mirror and deflection structure can be fabricated, for example, in a front-end process at wafer level. Then, a dielectric mirror and then a layer are deposited on a wafer with an epitaxially grown semiconductor body, and the layer is subsequently patterned with one-dimensional trenches, for example, by lithography. The wafer is then cut, resulting in individual optoelectronic components.

Alternatively, the deflection structure can also be applied to the semiconductor body in the back-end process. In this example, the deflection structure is produced separately, for example, by etching one side of a glass platelet, which is then placed downstream of the exit surface of the semiconductor body. The dielectric mirror and/or a conversion element can also be applied to an opposite side of the glass platelet beforehand.

The optical element may comprise a meta lens. A meta lens has a patterning in the refractive index in directions parallel to its main extension direction. The structuring may be periodic or aperiodic. Regions of the same refractive index each have a lateral extent, measured parallel to the main extension plane of the meta lens, of, for example, at most 1 μm and/or at least 2 nm.

In particular, the meta lens is arranged on the semiconductor body such that its main extension plane is parallel to that of the semiconductor body. The meta lens has, for example, a thickness, measured perpendicular to its main extension plane, of at most 5 μm or at most 1 μm or at most 500 nm or at most 100 nm.

The meta lens may be a converging lens or diverging lens. The meta lens may be configured to produce an asymmetric far field. Also, the meta lens may be arranged to produce a structured far field, which may be desired, for example, in IR applications. For example, the meta lens also acts to scatter the radiation passing through it in the x-direction and scatter it less or not at all in the y-direction. All features disclosed in connection with the deflection structure with respect to the aperture angle asymmetry in x- and y-direction are accordingly also disclosed for the meta lens.

For example, the meta lens is formed from at least two materials of different refractive indices. The materials are arranged in succession along the main extension plane, forming the patterning in refractive index. For example, one material is SiO₂ and another material is NbO₂. Similarly, the materials mentioned in connection with the dielectric layers can be used. Alternatively or additionally, the meta lens may have holes extending through the meta lens perpendicular to the main extension plane, forming regions of a refractive index.

A photonic crystal can also be used instead of or in addition to a meta lens.

A polarization filter, in particular a reflective polarization grating, may be arranged between the meta lens and the semiconductor body. The polarization filter is configured to polarize the radiation generated in the component and incident on the polarization filter and to transmit radiation of only one polarization direction. The radiation reflected from the polarization filter can be repolarized by scattering processes in the component and then transmitted when it next strikes the polarization filter.

Meta lenses also provide efficient deflection if the radiation hits the meta lens as directionally as possible and/or as polarized as possible. With a directional emission achieved by the dielectric mirror as a basis, a meta lens can also image broadband white light well into a desired far field. In this respect, the upstream dielectric mirror and/or the upstream polarization filter are advantageous. Meta lenses offer the advantage that they can be designed to be much flatter than conventional lenses, making the entire component more compact. Also, with meta lenses, all structures can be applied in the front-end process, which enables the production of chip-size package components.

The component may comprise a conversion element configured to convert radiation generated in the component. For example, the conversion element converts the primary radiation into a secondary radiation during operation.

The conversion element comprises or consists of one or more conversion materials. These may be sintered to a ceramic conversion element or pressed to a conversion element. Alternatively, the conversion element may comprise a matrix, for example, of silicone, in which the conversion material is embedded and distributed.

The conversion material can be, for example, a garnet or a nitride or an oxide or an oxynitride. Alternatively, the conversion material may be based on a semiconductor such as CdSe, CdTe, CdS. For example, the conversion material then comprises quantum dots and/or nanoplatelets of semiconductor material.

The optical element may comprise the conversion element. That is, the dielectric mirror is arranged between the conversion element and the exit surface. In operation, for example, unconverted primary radiation then impinges on the dielectric mirror. The predetermined wavelength is then preferably a wavelength for which the primary radiation provides significant intensity. For example, the predetermined wavelength is then the one at which the intensity distribution of the primary radiation has its global maximum.

The dielectric mirror may have a higher transmittance for radiation of the predetermined wavelength with large angles of incidence in the first angular range than for radiation of the predetermined wavelength with small angles of incidence in the first angular range. In particular, the transmittance is greater for at least some angles of incidence in the first angular range and greater than 0° than the transmittance at 0°. For example, the transmittance for all angles of incidence between and including 0.6·α and 0.9·α is greater such as at least 5% greater, than for all angles of incidence between and including 0° and 0.3·α.

For example, if the primary radiation is emitted from the exit surface with Lambertian distribution, the primary radiation passing through the dielectric mirror has essentially the same intensity/radiant intensity for all angles in the first angular range, preferably even with an excess at larger angles. The intensity drops sharply at the transition to the second angular range.

For components with radiation conversion, especially for white light emitting components, the color locus depends on the viewing angle. Thereby the proportion of converted light (for example, yellow light) is typically higher at flat angles than when looking at the luminous surface from the front. The reason for this is the longer optical path length of the primary radiation (for example, blue light) through the conversion element and thus higher absorption for flat emission angles. In the application, however, a uniform color appearance is often desired regardless of the viewing angle.

In the dielectric mirror between the conversion element and the semiconductor body, primary radiation is cut off in the second angular range. In the first angular range, higher transmission occurs at flatter emission angles (larger incidence angles) than at steeper emission angles (smaller incidence angles). This leads to overcompensation of the stronger absorption of primary radiation in the conversion element at flatter emission angles and thus to a more homogeneous chromaticity distribution in the first angular range.

The conversion element may be arranged between the dielectric mirror and the exit surface. The conversion element may generate secondary radiation upon conversion of radiation generated in the component, in particular primary radiation. The conversion element can be set up for full conversion or partial conversion.

The dielectric mirror may be transmissive to secondary radiation incident on the dielectric mirror at angles of incidence in the predetermined first angular range. Similarly, the dielectric mirror may be transmissive to primary radiation incident on the dielectric mirror with angles of incidence in the predetermined first angular range.

The dielectric mirror may be reflective for secondary radiation incident on the dielectric mirror with angles of incidence in the predetermined second angular range. Similarly, the dielectric mirror may be reflective for primary radiation incident on the dielectric mirror with angles of incidence in the predetermined second angular range.

A further dielectric mirror may be arranged between the conversion element and the exit surface. Like the dielectric mirror, the further dielectric mirror may comprise a plurality of dielectric layers. All features disclosed in connection with the dielectric mirror are also disclosed for the further dielectric mirror.

The further dielectric mirror may be transmissive to primary radiation incident on the further dielectric mirror at angles of incidence in the predetermined first angular range.

The further dielectric mirror may be reflective for primary radiation incident on the further dielectric mirror in the predetermined second angular range.

The further dielectric mirror can be reflective at all angles of incidence for the secondary radiation.

The exit surface may have a structuring. For example, the exit surface is roughened. An average roughness of the exit surface is then, for example, at least 500 nm or at least 1000 nm. By structuring the exit surface, a redistribution of the radiation reflected by the dielectric mirror or mirrors can be achieved so that, when it next impinges on a dielectric mirror, it impinges on the respective dielectric mirror, if necessary, with an angle of incidence in the first angular range.

A planarization layer may be applied to the exit surface, which is planar and/or smooth on a side facing away from the semiconductor body. In particular, the planarization layer is applied directly to the exit surface. In particular, the planarization layer is then arranged between the dielectric mirror and the exit surface. The planarization layer preferably comprises a material that is transparent to the radiation generated in the component, in particular the primary radiation or converted radiation such as silicon dioxide (SiO₂). The planarization layer simplifies and improves the deposition of the dielectric mirrors.

A glass platelet may be arranged between the meta lens and the dielectric mirror or between the meta lens and the polarization filter. The glass platelet may be self-supporting. For example, the glass platelet has an average thickness of at least 50 μm and/or at most 500 μm.

For the fabrication of the component with meta lens and glass platelet, for example, a meta lens designed for the desired far field is fabricated on a first side of a glass wafer. On an opposite second side, the dielectric mirror and/or the polarization filter are deposited. Further, a conversion element may be deposited on this second side. The glass wafer is separated into individual glass platelets, each with a meta lens, a dielectric mirror and/or a polarization filter, and optionally with a conversion element. These are then bonded to exit surfaces of semiconductor bodies. Alternatively, it is also possible to apply the glass wafer with the various elements as a composite to a wafer with an epitaxially grown semiconductor body, and then to separate the glass wafer together with the semiconductor body wafer into individual components.

Instead of forming the polarization filter and/or the dielectric mirror or the conversion element on the second side of the glass wafer, one or more of these elements can also be formed on the exit surface of the semiconductor body, for example, already in the front-end process on the wafer, and then the glass wafer or the glass wafer with the meta lens is applied to the semiconductor body.

The component may emit white light during operation. In particular, a mixture of the primary radiation and the radiation resulting from conversion forms white light.

Alternatively, however, it is also possible that the radiation emitted by the component during operation is radiation in the red and/or infrared spectral range. For example, the primary radiation is in the red or infrared spectral range and the radiation produced by conversion is in the infrared range. The component is then suitable, for example, as a radiation source in spectrometer or sensor applications.

Next, the illumination device is specified.

The illumination device may comprise an optoelectronic component described herein. Further, the component comprises a light guide (also referred to as a waveguide) having an in-coupling side via which radiation coming from the component is coupled into the light guide during operation. For example, the component is directly or indirectly attached to the coupling side.

During operation, the radiation coupled into the light guide is guided along the light guide and possibly selectively coupled out again in places. The light guide comprises or consists of glass or plastic, for example. The light guide is, for example, a solid body.

The light guide may be platelet-shaped with two opposite main sides. The main sides run in particular parallel to each other. The main sides can be flat or curved. The thickness of the light guide, measured as the distance between the main sides, is preferably less than the extent of the main sides in each direction. Extensions of the waveguide along the main sides are, for example, at least five times or at least ten times or at least 20 times the thickness of the light guide. For example, a thickness of the light guide is at most 1 mm or at most 500 μm. Expansions along the main sides are, for example, at least 1 cm or at least 5 cm.

The in-coupling side may be formed by a transverse side connecting the main sides. The transverse side has a smaller area than each of the main sides. For example, the area of the transverse side is at most one fifth or at most one tenth or at most 1/20 of the area of the main sides. The transverse side is elongated and preferably rectangular. The main sides may each be rectangular.

Via one of the main sides, the radiation entering via the in-coupling side can be coupled out again during operation. The illumination device is then particularly suitable as background lighting for a display, for example, a smartphone display or a display for a vehicle interior.

For example, the component is one with a deflection structure as described above or a meta lens. The component is then preferably arranged on the in-coupling side such that the x-direction runs parallel to the main sides or parallel to the longer edge of the transverse side and that the y-direction runs perpendicular to the main sides or parallel to the shorter edge of the transverse side.

In particular, the component is smaller than the transverse side/in-coupling side so that, in top view, the component lies completely within the transverse side. Preferably, the illumination device comprises several components as described here, which are arranged one behind the other in a direction parallel to the longer edge of the transverse side and whose radiation is coupled into the light guide via the in-coupling side in each example.

Further advantages and advantageous configurations and further developments of the optoelectronic component and the illumination device result from the following examples shown in connection with the figures. Elements which are identical, similar or have the same effect are provided with the same reference signs in the figures. The figures and the proportions of the elements shown in the figures are not to be regarded as to scale. Rather, individual elements, in particular layer thicknesses, may be shown exaggeratedly large for better representability and/or for better comprehensibility.

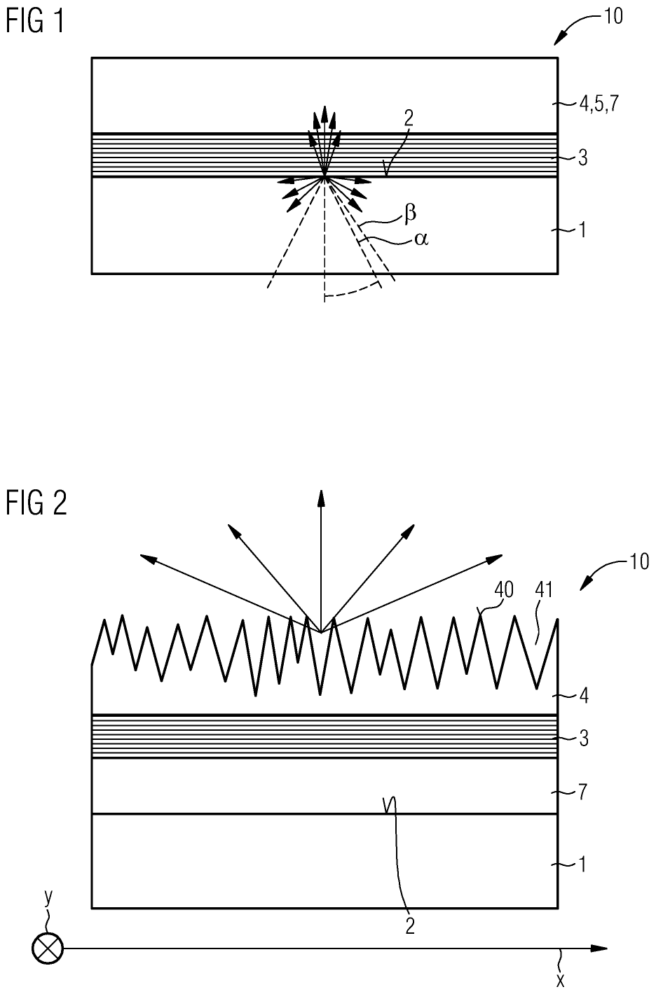

FIG. 1 shows a first example of an optoelectronic component 10 in cross-sectional view. The component 10 comprises a semiconductor body 1, for example, based on AlInGaN with an active region (not shown). In the active region, an incoherent primary radiation is generated during intended operation. In this example, the primary radiation is, for example, radiation in the blue spectral range.

A dielectric mirror 3 is arranged on an exit surface 2 of the semiconductor body 1. A large part of the primary radiation generated by the semiconductor body 1 emerges from the semiconductor body 1 via the exit surface 2 during intended operation of the component 10. The dielectric mirror 3 is configured to be transmissive for primary radiation incident with angles of incidence in a first angular range between 0° and a inclusive, and to be reflective for primary radiation incident with angles of incidence in a second angular range outside the first angular range (from β to 90°). In this example, the value for a is, for example, 30°. For example, the value for β is 35°.

On the side of the dielectric mirror 3 facing away from the semiconductor body 1, an optical element 4, 5, 7 is arranged which is set up to deflect and/or convert the radiation passing through. For this purpose, the optical element 4, 5, 7 has, in particular, a thickness of at least one quarter of the wavelength at which the primary radiation has its intensity maximum.

FIG. 2 shows a second example of the optoelectronic component 10. A conversion element 7 is arranged between the dielectric mirror 3 and the exit surface 2. In operation, the conversion element 7 converts the primary radiation into a secondary radiation, for example, into light in the yellow to green and/or orange to red spectral range. The dielectric mirror 3 is transmissive for secondary radiation incident with angles of incidence in the first angular range and reflective for secondary radiation incident with angles of incidence in the second angular range. The dielectric mirror 3 may have the same angular selectivity for the primary radiation. The light passing through the dielectric mirror 3 is in particular a mixture of the primary radiation and the secondary radiation, resulting, for example, in white light.

In this example, the optical element is a deflection structure 4, for example, made of glass or transparent silicone or transparent plastic or SiO₂ or NbO₂ or TiO₂ or SiN, which comprises a structuring with trenches 41 extending in a y-direction on a scattering side 40 facing away from the semiconductor body 1. The view of FIG. 2 shows a cross section perpendicular to the y-direction and parallel to an x-direction, wherein the profile of the scattering side 40 has alternating elevations and depressions along the x-direction.

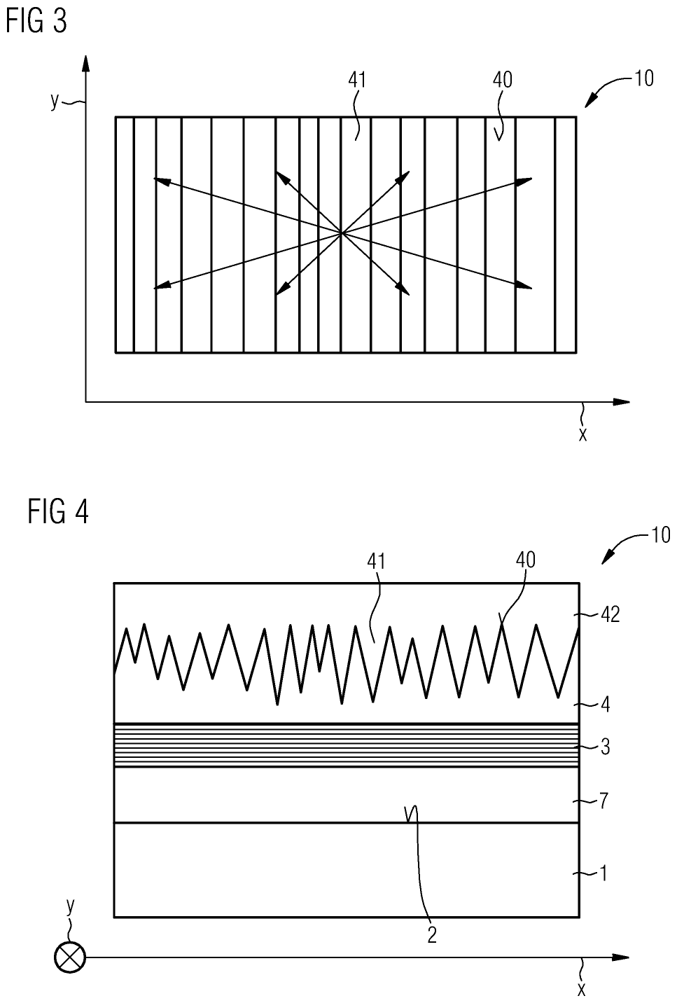

FIG. 3 shows the component of FIG. 2 in plan view of the scattering side 40. It can be seen that the trenches 41 extend linearly in the y-direction and over the entire extent of the deflection structure 4 in this direction.

The effect of the deflecting structure 4 on the radiation passing through is indicated by the arrows in FIGS. 2 and 3. In the x-direction, the radiation initially directed or focused by the mirror 3 and incident on the scattering side 40 is dispersed by the structuring. In the y-direction, the directed radiation essentially retains its directionality.

The third example of FIG. 4 is similar to that of FIG. 2. In FIG. 2, the scattering side 40 adjoins air, resulting in a refractive index jump at this side. In FIG. 4, the scattering side 40 adjoins an encapsulation layer 42 that fills the trenches 41. The encapsulation layer 42 is chosen so that its refractive index is different from that of the deflection structure 4. For example, the encapsulation is made of SiO₂ or SiN. On a side facing away from the deflection structure 4, the encapsulation layer 42 is planar and/or smooth. This allows easy mounting, for example, on the in-coupling side of a light guide.

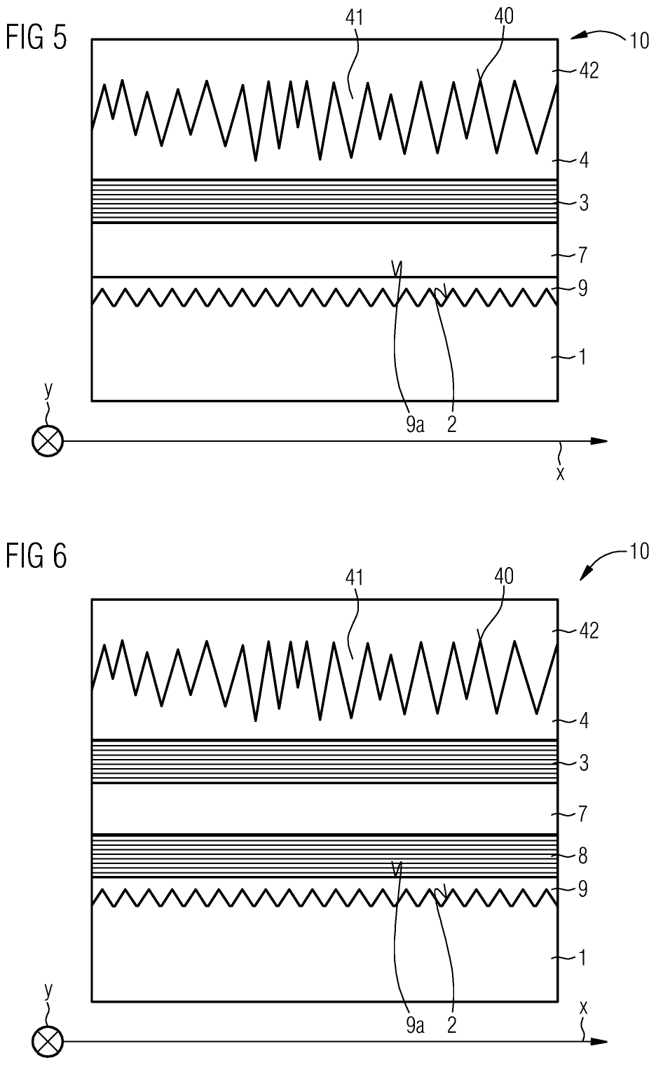

FIG. 5 shows a fourth example of the optoelectronic component 10, again in cross-sectional view. It is similar to FIG. 3. The exit surface 2 of the semiconductor body 1 is additionally structured/roughened. Radiation reflected back from the dielectric mirror 3 can be redistributed by the structuring and, if applicable, impinge on the dielectric mirror 3 in the first angular range when it next impinges.

A planarization layer 9, for example, of SiO₂, is applied here to the structured exit surface 2, which is planar and smooth on a side 9a facing away from the semiconductor body 1. The average roughness of the side 9a is less than 1 nm, for example.

FIG. 6 shows a fifth example of the optoelectronic component 10. This is supplemented with a further dielectric mirror 8 compared to the previous example. The further dielectric mirror 8 is arranged between the conversion element 7 and the semiconductor body 1. The further dielectric mirror 8 is transmissive for primary radiation incident with angles of incidence in the first angular range, and reflective for primary radiation incident with angles of incidence in the second angular range. For secondary radiation, the further dielectric mirror 8 may be reflective. The dielectric mirror 3 exhibits the angular selectivity described above at least for the secondary radiation.

The use of two dielectric mirrors offers the advantage that each dielectric mirror can then be controlled for a specific wavelength range (primary radiation or secondary radiation).

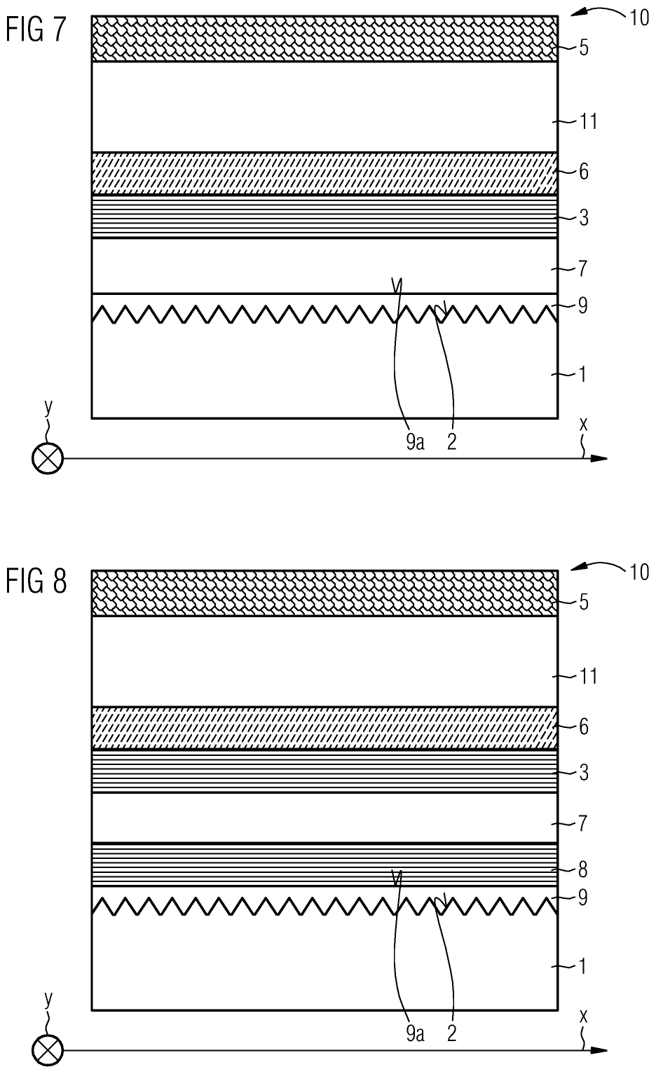

FIG. 7 shows a sixth example of the optoelectronic component 10. It is similar to that of FIG. 5, except that here the deflection structure 4 with the applied encapsulation 42 is replaced by an optical element comprising a glass platelet 11, on one side of which a meta lens 5 is arranged and on the other side a polarization filter 6 is arranged. Thanks to the upstream dielectric mirror 3 and the polarization filter 6, polarized directional white light strikes the meta lens 5, which can then efficiently focus or diffuse the light.

The seventh example of the optoelectronic component 10 shown in FIG. 8 comprises, like the fifth example, a further dielectric mirror 8 in front of the conversion element 7.

Instead of arranging the polarization filter 6 between the glass platelet 11 and the dielectric mirror 3, the polarization filter 6 could also be arranged between the dielectric mirror 3 and the semiconductor body 1, in particular between the dielectric mirror 3 and the conversion element 7.

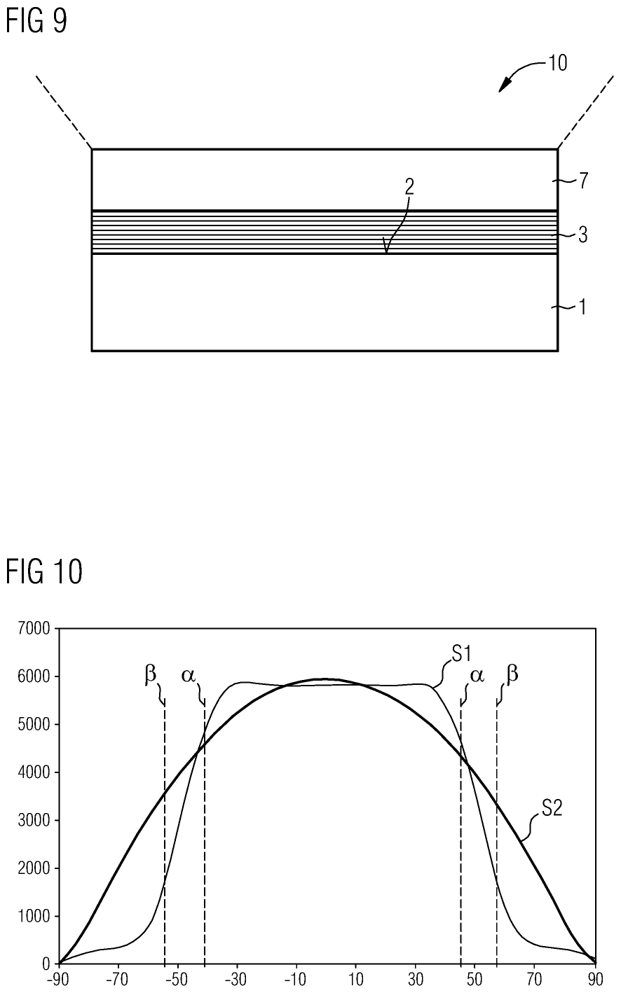

FIG. 9 shows an eighth example of the optoelectronic component 10 in which the optical element is a conversion element 7. The dielectric mirror 3 exhibits the above-mentioned angular selectivity for the primary radiation. For example, for the secondary radiation formed by conversion by the conversion element 7, the dielectric mirror 3 is reflective at all angles of incidence.

The angular selectivity of the dielectric mirror 3 of FIG. 9 is exemplified by FIG. 10. The curve S2 shows the far-field radiation distribution of a Lambertian radiator. On the x-axis angles between −90° and 90°, measured to a normal to the emission surface of the Lambertian radiator, are shown. On the y-axis, the radiation intensity is plotted. The previously described semiconductor bodies 1 form such a Lambertian radiator in good approximation with the exit surface 2 as the emission surface.

The curve S1 shows the far-field radiation distribution when the dielectric mirror 3 is applied to the emission surface. The dielectric mirror 3 has a high angular selectivity for the primary radiation. Presently, the dielectric mirror 3 is transmissive for radiation with angles of incidence in a first angular range from 0° to α and reflective for radiation with angles of incidence larger than β. Moreover, for larger angles of incidence in the first angular range, the transmittance is higher than for smaller angles of incidence. As a result, the primary radiation passing through the dielectric mirror 3 at the edge of the first angular range has a similar, even slightly higher, radiant intensity than at the center of the first angular range. This results in a more uniform color impression after conversion, which is almost independent of the viewing angle.

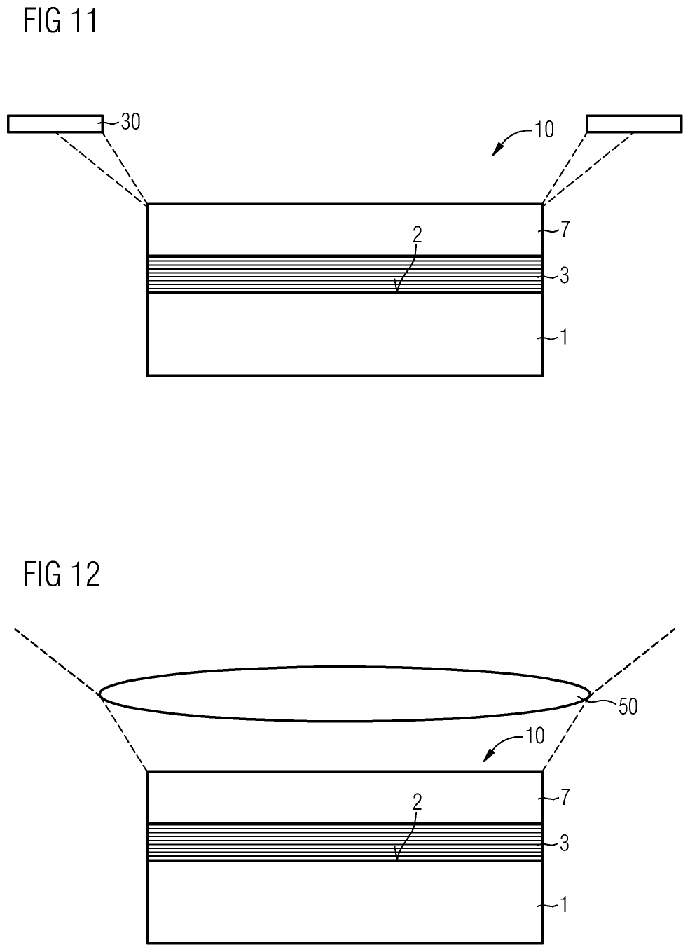

FIG. 11 shows an example of an illumination device. The previously described component 10 is followed by an aperture 30, which additionally cuts off the emission angles that lie outside the homogeneous color range.

FIG. 12 shows another example of an illumination device in which a lens 50 is arranged downstream of the component 10, with which the homogeneous color impression is imaged onto a larger angular range.

The aperture 30 of FIG. 11 and the lens 50 of FIG. 12 may also be combined in an illumination device.

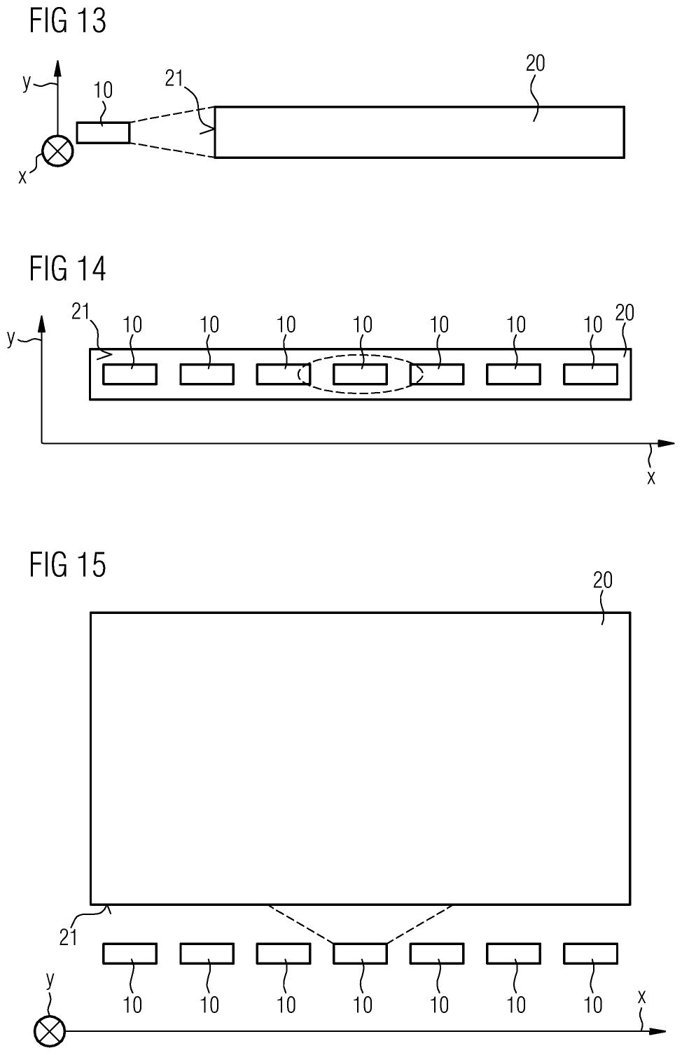

FIGS. 13 to 15 show an example of an illumination device in various views. The illumination device comprises a plurality of optoelectronic components 10, for example, those as shown in FIGS. 2 to 8, and a light guide 20 having an in-coupling side 21. Radiation, for example, white light, emitted from the components 10 during operation enters the light guide 20 via the on-coupling side 21 and is then distributed inside the light guide 20.

The light guide 20 is designed in the form of a platelet and has two opposite main sides which are connected to each other by the in-coupling side 21 and which are each substantially larger than the in-coupling side 21. Via one or both main sides, the coupled-in radiation is preferably homogeneously coupled out. The illumination device is, for example, a display backlight.

As can be seen from FIG. 14, the in-coupling side 21 is rectangular and elongated. Along the longer edge of the in-coupling side 21, the components 10 are arranged one behind the other and spaced apart. The x-direction along which the radiation emitted by the components 10 is dispersed is parallel to the longer edge. The y-direction, along which the radiation emitted by the components 10 has a small aperture angle, is parallel to the shorter edge of the coupling side 21. In this way, the radiation emitted by the components 10 is efficiently coupled into the platelet-shaped light guide 20. The beam path or beam spot of a component 10 is indicated by the dashed lines in FIGS. 13 to 15.

Our components and devices are not limited by the description in conjunction with the examples. Rather, this disclosure comprises any new feature as well as any combination of features, particularly including any combination of features in the appended claims, even if the feature or the combination per se is not explicitly stated in the claims or examples.

1-16. (canceled)

17. An optoelectronic component comprising:
a semiconductor body having an active region that generates primary electromagnetic radiation and an exit surface;
an optical element arranged downstream of the exit surface that deflects and/or converts radiation generated in the component; and
a dielectric mirror between the exit surface and the optical element,
wherein the dielectric mirror is transmissive to radiation of a predetermined wavelength generated in the component and incident at angles of incidence in a predetermined first angular range, and is reflective to the radiation of the predetermined wavelength incident at angles of incidence in a predetermined second angular range.

18. The optoelectronic component according to claim 17, wherein
the first angular range comprises all angles of incidence of 0° to α measured to a normal to the dielectric mirror, and
the second angular range comprises all angles of incidence of at least β measured with respect to the normal to the dielectric mirror, wherein β≥α.

19. The optoelectronic component according to claim 18, wherein the optical element comprises a deflection structure configured such that radiation from the component passing through the deflection structure is scattered in an x-direction and is less or not scattered in a y-direction, perpendicular to the x-direction.

20. The optoelectronic component according to claim 19, wherein the deflection structure has on a scattering side a structuring with trenches extending in the y-direction.

21. The optoelectronic component according to claim 17, wherein the optical element comprises a meta lens.

22. The optoelectronic component according to claim 21, wherein a polarization filter is arranged between the meta lens and the semiconductor body.

23. The optoelectronic component according to claim 17, wherein the component comprises a conversion element configured to convert radiation generated in the component.

24. The optoelectronic component according to claim 23, wherein
the optical element comprises the conversion element, and
the dielectric mirror has a higher transmittance for radiation of the predetermined wavelength with large angles of incidence in the first angular range than for radiation of the predetermined wavelength with small angles of incidence in the first angular range.

25. The optoelectronic component according to claim 23, wherein
the conversion element is arranged between the dielectric mirror and the exit surface, the conversion element generating secondary radiation upon conversion of radiation generated in the component,
the dielectric mirror is transmissive to secondary radiation incident on the dielectric mirror at angles of incidence in the predetermined first angular range, and
the dielectric mirror is reflective for secondary radiation incident on the dielectric mirror with angles of incidence in the predetermined second angular range.

26. The optoelectronic component according to claim 25, wherein
a further dielectric mirror is arranged between the conversion element and the exit surface,
the further dielectric mirror is transmissive for primary radiation incident on the further dielectric mirror with angles of incidence in the predetermined first angular range, and
the further dielectric mirror is reflective for primary radiation incident on the further dielectric mirror in the predetermined second angular range.

27. The optoelectronic component according to claim 17, wherein
the exit surface has a structuring, and
a planarization layer is applied to the exit surface, which is planar on a side facing away from the semiconductor body.

28. The optoelectronic component according to claim 21, wherein a glass platelet is arranged between the meta lens and the dielectric mirror.

29. The optoelectronic component according to claim 17, wherein the component emits white light during operation.

30. An illumination device comprising:
the optoelectronic component according to claim 17; and
a light guide with an in-coupling side via which radiation coming from the component is coupled into the light guide during operation.

31. The illumination device according to claim 30, wherein
the light guide is platelet-shaped with two opposite main sides, and
the in-coupling side is formed by a transverse side connecting the main sides, the area of said transverse side being smaller than that of the main sides.

32. An optoelectronic component comprising:
a semiconductor body having an active region that generates primary electromagnetic radiation and an exit surface;
a meta lens located downstream of the exit surface; and
a polarization filter between the meta lens and the exit surface,
wherein the meta lens is formed from at least two materials of different refractive indices, and
the materials are arranged in succession along the main extension plane so that the meta lens has a patterning in refractive index in directions parallel to its main extension plane.

33. An optoelectronic component comprising:
a semiconductor body having an active region that generates primary electromagnetic radiation and an exit surface;
an optical element arranged downstream of the exit surface that deflects and/or converts radiation generated in the component; and
a dielectric mirror between the exit surface and the optical element,
wherein the dielectric mirror is transmissive to radiation of a predetermined wavelength generated in the component and incident at angles of incidence in a predetermined first angular range, and is reflective to the radiation of the predetermined wavelength incident at angles of incidence in a predetermined second angular range, and
the optical element comprises a deflection structure configured such that radiation from the component passing through the deflection structure is scattered in an x-direction and is less or not scattered in a y-direction, perpendicular to the x-direction.
